(19) United States
(12) Patent Application Publication
(10) Pub. No.: US 2007/0059902 A1
(43) Pub. Date: Mar. 15, 2007

(54) Method for manufacturing semiconductor device

(76) Inventor: Jae Hee Kim, Suwon-city (KR)

Correspondence Address: MCKENNA LONG & ALDRIDGE LLP;Song K. Jung, 1900 K Street, N.W., Washington, DC, 20006, US

(21) Appl. No.: 11/320,740

(22) Filed: Dec. 30, 2005

(30) Foreign Application Priority Data
Sep. 13, 2005 (KR) 2005-0085105

(51) Int. Cl. H01L 21/30

(52) U.S. Cl. 438/459

(57) ABSTRACT

A method for manufacturing a semiconductor device is disclosed, in which a laser marking is formed on a rear surface of a wafer to prevent a Cu layer from being peeled by a protrusion of the laser marking. The method includes forming a laser marking on a rear surface of each wafer, and grinding a protrusion formed by the laser marking.

### CROSS-REFERENCE TO RELATED APPLICATION

This application claims the benefit of Korean Patent Application No. P2005-0085105, filed on Sep. 13, 2005, which is hereby incorporated by reference as if fully set forth herein.

### BACKGROUND OF THE INVENTION

1. Field of the Invention

The present invention relates to a method for manufacturing a semiconductor device, and more particularly, to a method for manufacturing a semiconductor device in which a laser marking is formed on a rear surface of a wafer.

2. Discussion of the Related Art

Generally, a semiconductor device has a multilevel structure comprising various films such as a silicon film, an oxide film, a field oxide film, a polysilicon film, and metal line film. The semiconductor device is manufactured by various process steps such as a deposition process, an oxidation process, a photolithographic process (processes of coating, exposing and developing a photoresist film), an etching process, a cleaning process, and a rinsing process.

In other words, to selectively pattern a material layer deposited, a photoresist film is coated on the material layer by spin coating and then irradiated through a mask to undergo an exposure process. Afterwards, the photoresist film is developed to form a desired photoresist mask pattern on the material layer. The material layer is then selectively etched using the patterned photoresist film as a mask to obtain a desired pattern.

The processes of depositing and etching the material layer are repeated to manufacture a semiconductor device on a wafer. At this time, if the process steps are performed in error, a defect of the semiconductor device results and leads to waste. Therefore, it is necessary to check how respective wafers are manufactured and the current status of the wafers. In this respect, a laser marking is formed on each wafer to check the status of the wafer.

FIG. 1 is a sectional view illustrating a laser marking formed on a general wafer, and FIG. 2 is a plan view illustrating a laser marking formed on a general wafer.

As shown in FIG. 1, a laser marking 20 is formed on an edge of a wafer 10. At this time, the laser marking 20 is deeply formed to have a depth D so that the wafer 10 can be checked even though various metal layers are formed on the wafer in accordance with the high integration of a semiconductor device. A byproduct of the wafer 10, i.e., a protrusion 22, is formed on a surface of the wafer 10 at a predetermined height H when the laser marking 20 is formed by irradiating laser.

If a metal line layer of Cu is formed as a seventh layer in the process of manufacturing a semiconductor device, the laser marking 20 has a depth D in the range of 4 μm to 7 μm and the protrusion 22 has a height H in the range of 2 μm to 3 μm. Also, as shown in FIG. 2, the laser marking 20 is generally formed at an interval of 3.0 mm from the edge of the wafer 10.

A conventional process for forming the metal line layer of Cu will now be briefly described.

FIG. 3A to FIG. 3E are sectional views illustrating the conventional process steps for forming the metal line layer of Cu.

When the laser mark is in the wafer, a dual damascene structure (a combined structure of a contact hole and a trench) can be formed on an insulating film of the wafer before the metal line layer of Cu is formed.

Referring to FIG. 3A to FIG. 3E, to form the metal line layer of Cu, a photo etching process (PEP) for forming a trench is performed on the insulating film 30 in which a contact hole is formed.

In more detail, as shown in FIG. 3A, a photoresist film (not shown) is coated on the insulating film 30 and then patterned by exposing and developing processes that use a mask. The insulating film 30 is etched at a predetermined depth using the patterned photoresist film as a mask so that the dual damascene structure is formed.

At this time, the trench is formed at the edge of the wafer, excluding some of the edge through wafer edge exclusion (WEE). In other words, since the laser marking is formed at the excluded edge, the trench pattern is removed therefrom to display the laser marking.

As shown in FIG. 3B, a Cu layer 40 is formed by an electro copper plating (ECP) process on the entire surface of the wafer 10, including the insulating film 30 having the dual damascene structure. At this time, the laser marking 20 and the trench are filled with the Cu layer 40.

As shown in FIG. 3C, the Cu layer 40 formed at an interval of 2.5 mm to 3.0 mm from the edge of the wafer 10 is removed by an edge bead removal (EBR) process. At this time, if the Cu layer 40 is formed on the wafer edge, various contamination problems are caused. Therefore, the wafer edge is chemically removed.

The EBR region is formed on the wafer edge at a range narrower than the WEE region of the trench. If the EBR region is greater than the WEE region of the trench, the insulating film of the trench pattern corresponding to a portion not filled with the Cu layer may be destroyed during a chemical mechanical polishing (CMP) process of the Cu layer, thereby causing particle sources. Therefore, the EBR region is formed in the vicinity of the wafer edge at a range narrower than the WEE region of the trench.

As shown in FIG. 3D, the Cu layer 40 is polished by the CMP process to expose a surface of the insulating film 30 to result in a Cu line 40a being formed.

However, the conventional process of manufacturing a semiconductor device has the following problems.

First, as shown in FIGS. 3E and 4A, the laser marking formed on each wafer to display the process status of the respective layers generates a defect due to the protrusion of the laser marking. For example, the Cu layer remains at a sidewall of the protrusion due to the protrusion of the laser marking during the CMP process.

For this reason, a Cu belt is formed at the wafer edge even though the EBR process is performed, thereby causing various contamination problems. As shown in FIG. 4B, a problem occurs in that the Cu layer peels during the CMP process.

### SUMMARY OF THE INVENTION

Accordingly, the present invention is directed to a method for manufacturing a semiconductor device which substantially obviates one or more problems due to limitations and disadvantages of the related art.

The present invention provides a method for manufacturing a semiconductor device in which a laser marking is formed on a rear surface of a wafer to prevent a Cu layer from being peeled by a protrusion of the laser marking.

Additional advantages, and features of the invention will be set forth in the description which follows and will become apparent to those having ordinary skill in the art upon examination of the following. These and other advantages of the invention may be realized and attained by the structure particularly pointed out in the written description and claims hereof as well as the appended drawings.

To achieve these and other advantages and in accordance with the invention, as embodied and broadly described herein, a method for manufacturing a semiconductor device includes forming a laser marking on a rear surface of each wafer, and grinding a protrusion formed by the laser marking.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention illustrate exemplary embodiments of the invention and together with the description serve to explain the principle of the invention. In the drawings:

FIG. 1 is sectional view illustrating a laser marking formed on a general wafer;

FIG. 2 is a plan view illustrating a laser marking formed on a general wafer;

FIG. 3A to FIG. 3E are sectional views illustrating conventional process steps of forming a metal line layer of Cu; and

FIG. 4A and FIG. 4B illustrate the peeling of the Cu layer shown in FIG. 3E.

FIG. 5A and FIG. 5B are sectional views illustrating a semiconductor device manufactured in accordance with an exemplary embodiment of the present invention.

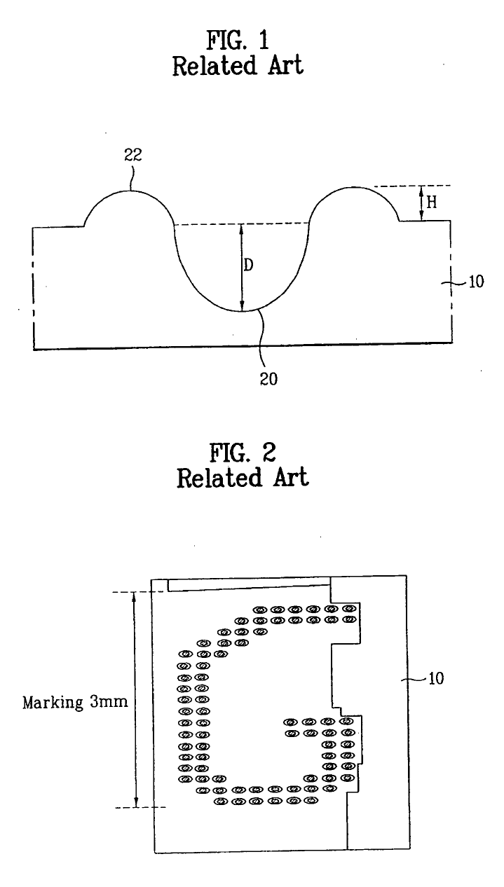

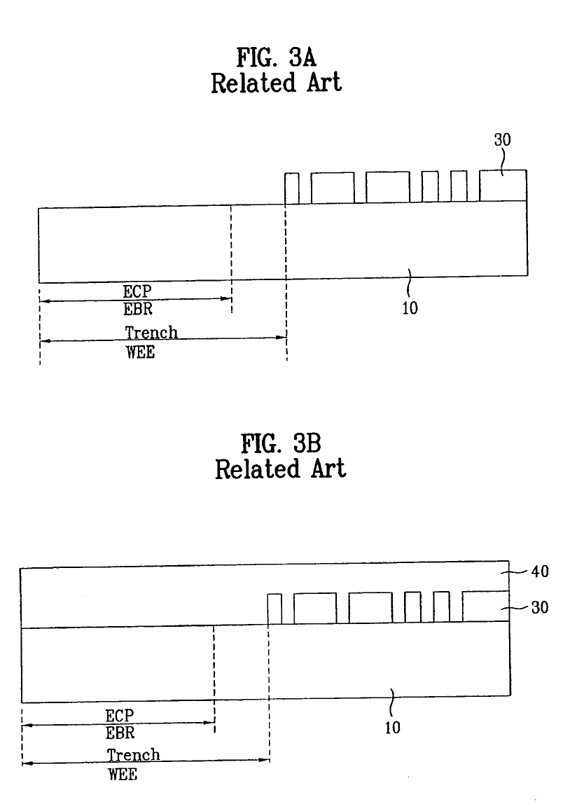

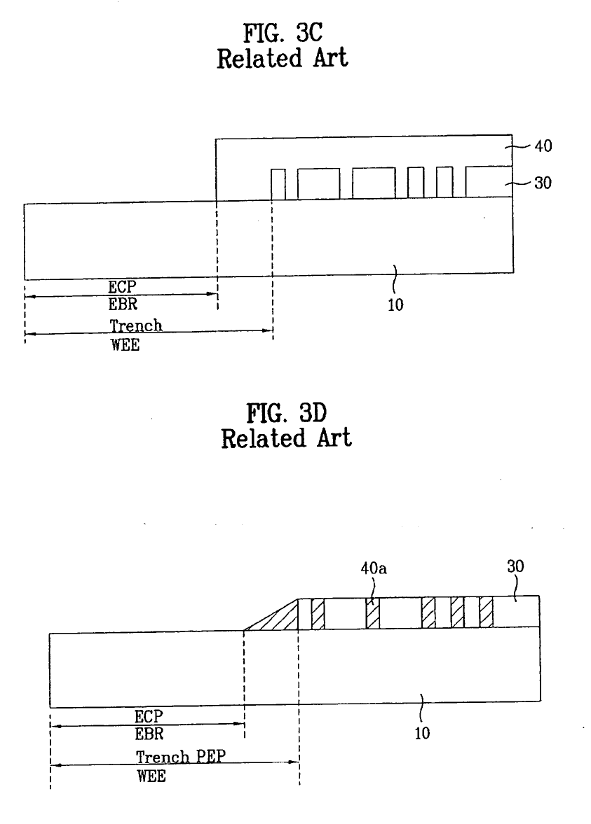

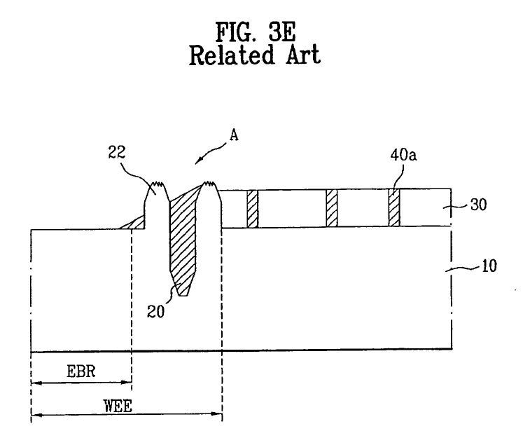

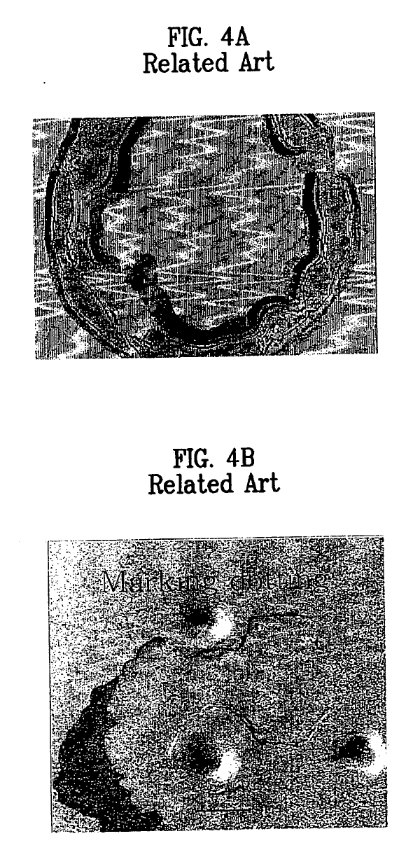

### DETAILED DESCRIPTION OF THE INVENTION

Reference will now be made in detail to the preferred embodiments of the present invention, examples of which are illustrated in the accompanying drawings. Wherever possible, the same reference numbers will be used throughout the drawings to refer to the same or like parts.

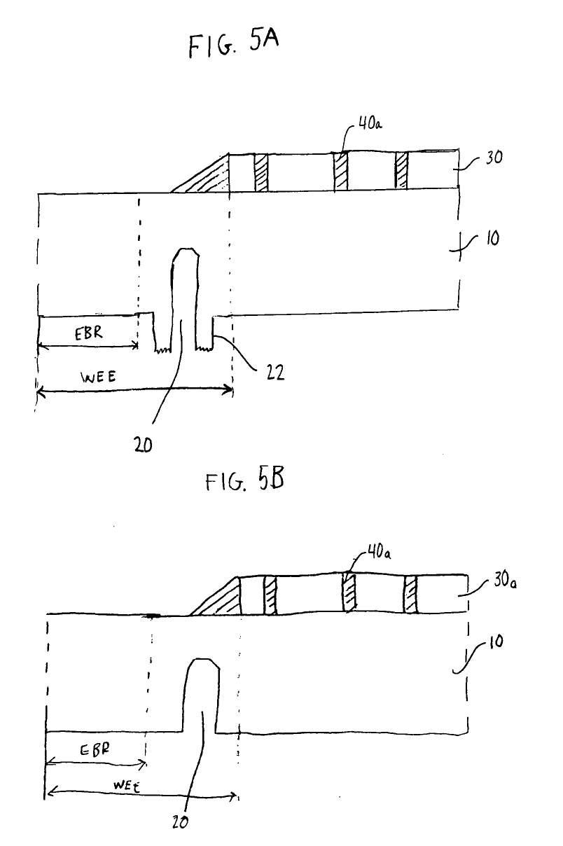

As shown in FIG. 5A, in a method for manufacturing a semiconductor device according to the present invention, a laser marking 20 is not formed on a front surface of each wafer, but instead is formed on a rear surface of the wafer 10. The Cu layer 40a is formed as described above.

The laser marking 20 is formed on the rear surface of the wafer 10 is spaced apart from a wafer bevel at an interval of 10 mm or greater.

As described with reference to the related art, a protrusion 22 is formed at a thickness of 2 μm to 3 μm when the laser marking is formed. In this case, the protrusion can causes the wafer to be detached from a vacuum absorption chuck or an electrostatic (ESC) chuck of a stage that fixes the wafer. Therefore, as shown in FIG. 5B, the protrusion of the laser marking is ground to prevent the wafer from being detached from the chuck by the protrusion, thereby failing to cause damage of the wafer.

In other words, the protrusion of the laser marking is selectively ground. At this time, the protrusion of the laser marking has a step difference with a surface of the wafer in the range of 1000 Å or less.

Furthermore, the wafer with the laser marking is cleaned. At this time, impurities on the rear surface of the wafer may be transferred onto the front surface of the wafer.

Therefore, the respective wafers are cleaned after they are arranged to face each other. In other words, the cleaning process is performed in a state in which the front surfaces of the respective wafers face each other and their rear surfaces face each other.

Since the laser marking for displaying the process status of the respective layers is formed on the rear surface of the wafer, it is possible to prevent the Cu layer from being peeled by the protrusion of the laser marking. In addition, it is possible to avoid a defect of the wafer due to peeling of the Cu layer.

It will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

What is claimed is:

1. A method for manufacturing a semiconductor device comprising:
forming a laser marking on a rear surface of a wafer; and
grinding a protrusion formed by the laser marking.

2. The method as claimed in claim 1, wherein the laser marking is formed spaced apart from a wafer bevel at an interval of 10 mm or greater.

3. The method as claimed in claim 1, wherein the protrusion of the laser marking is ground to maintain a step difference with a surface of the wafer in the range of 1000 Å or less.

4. The method as claimed in claim 1, further comprising cleaning the ground wafer.

5. The method as claimed in claim 4, wherein a plurality of wafers are cleaned, and wherein the wafers have front surfaces and the rear surfaces, and wherein the wafers are cleaned in a state such that the front surfaces of the respective wafers face each other and the rear surfaces face each other.
